(19) United States
(12) Patent Application Publication
(10) Pub. No.: US 2020/0156995 A1
(43) Pub. Date: May 21, 2020

(54) WATER VAPOR STRENGTHENABLE ALKALI-FREE GLASS COMPOSITIONS

(71) Applicant: CORNING INCORPORATED, Corning, NY (US)

(72) Inventors: Timothy Michael Gross, Corning, NY (US); Adam Robert Sarafian, Painted Post, NY (US); Jingshi Wu, Painted Post, NY (US); Zheming Zheng, Horseheads, NY (US)

(21) Appl. No.: 16/681,995

(22) Filed: Nov. 13, 2019

Related U.S. Application Data
(60) Provisional application No. 62/768,342, filed on Nov. 16, 2018.

(51) Int. Cl. C03C 21/00; C03C 4/18; C03C 3/097; C03C 3/091; H05K 5/03

(52) U.S. Cl. CPC C03C 21/007; C03C 4/18; C03C 3/097; H05K 5/0017; H05K 5/03; C03C 2204/00; C03C 3/091

(57) ABSTRACT

Glass-based articles that include a compresive stress layer extending from a surface of the glass-based article to a depth of compression are formed by exposing glass-based substrates to water vapor containing environments. The glas-based substrates are substantially free or free of alkali metal oxides. The methods of forming the glass-based articles may include elevated pressures and/or multiple exposures to water vapor containing environments.

### CROSS-REFERENCE TO RELATED APPLICATIONS

This application claims the benefit of priority under 35 U.S.C. § 119 of U.S. Provisional Application Ser. No. 62/768,342 filed on Nov. 16, 2018, the content of which is relied upon and incorporated herein by reference in its entirety.

### BACKGROUND

### Field

This disclosure relates to glass-based articles strengthened by steam treatment, alkali-free glass compositions utilized to form the glass-based articles, and methods of steam treatment to strengthen the glass-based articles.

### Technical Background

Portable electronic devices, such as, smartphones, tablets, and wearable devices (such as, for example, watches and fitness trackers) continue to get smaller and more complex. As such, materials that are conventionally used on at least one external surface of such portable electronic devices also continue to get more complex. For instance, as portable electronic devices get smaller and thinner to meet consumer demand, the display covers and housings used in these portable electronic devices also get smaller and thinner, resulting in higher performance requirements for the materials used to form these components.

Accordingly, a need exists for materials that exhibit higher performance, such as resistance to damage, along with lower cost and ease of manufacture for use in portable electronic devices.

### SUMMARY

In aspect (1), a glass-based article is provided. The glass-based article comprises: a thickness of less than 2 mm; and a compressive stress layer extending from a surface of the glass-based article to a depth of compression. The glass-based article is substantially free of alkali oxides, the compressive stress layer comprises a compressive stress greater than or equal to 10 MPa, and the depth of compression is greater than 5 μm.

In aspect (2), a glass-based article of aspect (1) is provided, further comprising a hydrogen containing layer extending from the surface of the glass-based article to a depth of layer, wherein a hydrogen concentration of the hydrogen containing layer decreases from a maximum hydrogen concentration to the depth of layer.

In aspect (3), a glass-based article of aspect (1) or (2) is provided, wherein the compressive stress is greater than or equal to 100 MPa.

In aspect (4), a glass-based article of any of aspects (1) to (3) is provided, wherein the depth of compression is greater than or equal to 10 μm.

In aspect (5), a glass-based article of any of aspects (1) to (4) is provided, wherein the thickness is less than or equal to 1 mm.

In aspect (6), a glass-based article of any of aspects (1) to (5) is provided, wherein a glass having the same composition as the center of the glass-based article has a coefficient of thermal expansion of less than 10 ppm.

In aspect (7), a glass-based article of any of aspects (1) to (6) is provided, wherein the center of the glass-based article comprises greater than or equal to 2 mol % to less than or equal to 10 mol % P₂O₅.

In aspect (8), a glass-based article of any of aspects (1) to (7) is provided, wherein the center of the glass-based article comprises greater than or equal to 5 mol % to less than or equal to 10 mol % P₂O₅.

In aspect (9), a glass-based article of any of aspects (1) to (8) is provided, wherein the center of the glass-based article comprises greater than or equal to 15 mol % B₂O₃.

In aspect (10), a glass-based article of aspect (9) is provided, wherein the center of the glass-based article is substantially free of P₂O₅.

In aspect (11), a glass-based article of any of aspects (1) to (10) is provided, wherein the center of the glass-based article comprises SiO₂ and Al₂O₃.

In aspect (12), a glass-based article of any of aspects (1) to (11) is provided, wherein the center of the glass-based article comprises SnO₂.

In aspect (13), a glass-based article of any of aspects (1) to (12) is provided, wherein the center of the glass-based article comprises at least one of MgO, CaO, SrO, and BaO.

In aspect (14), a consumer electronic product is provided. The consumer electronic product comprises: a housing comprising a front surface, a back surface and side surfaces; electrical components at least partially within the housing, the electrical components comprising at least a controller, a memory, and a display, the display at or adjacent the front surface of the housing; and a cover substrate disposed over the display. At least a portion of at least one of the housing or the cover substrate comprises the glass-based article of any of aspects (1) to (13).

In aspect (15), a glass-based article is provided. The glass-based article comprises a compressive stress layer extending from a surface of the glass-based article to a depth of compression. The glass-based article is substantially free of alkali oxides, the compressive stress layer comprises a compressive stress greater than or equal to 10 MPa, the depth of compression is greater than 5 μm, and a glass having the same composition as the center of the glass-based article has a coefficient of thermal expansion of less than 10 ppm.

In aspect (16), a glass-based article of aspect (15) is provided, further comprising a hydrogen containing layer extending from the surface of the glass-based article to a depth of layer, wherein a hydrogen concentration of the hydrogen containing layer decreases from a maximum hydrogen concentration to the depth of layer.

In aspect (17), a glass-based article of aspect (15) or (16) is provided, wherein the compressive stress is greater than or equal to 100 MPa.

In aspect (18), a glass-based article of any of aspects (15) to (17) is provided, wherein the depth of compression is greater than or equal to 10 μm.

In aspect (19), a glass-based article of any of aspects (15) to (18) is provided, wherein the thickness is less than or equal to 1 mm.

In aspect (20), a glass-based article of any of aspects (15) to (19) is provided, wherein a glass having the same composition as the center of the glass-based article has a coefficient of thermal expansion of less than 8 ppm.

In aspect (21), a glass-based article of any of aspects (15) to (20) is provided, wherein the center of the glass-based article comprises greater than or equal to 2 mol % to less than or equal to 10 mol % P₂O₅.

In aspect (22), a glass-based article of any of aspects (15) to (21) is provided, wherein the center of the glass-based article comprises greater than or equal to 5 mol % to less than or equal to 10 mol % P₂O₅.

In aspect (23), a glass-based article of any of aspects (15) to (22) is provided, wherein the center of the glass-based article comprises greater than or equal to 15 mol % B₂O₃.

In aspect (24), a glass-based article of aspect (23) is provided, wherein the center of the glass-based article is substantially free of P₂O₅.

In aspect (25), a glass-based article of any of aspects (15) to (24) is provided, wherein the center of the glass-based article comprises SiO₂ and Al₂O₃.

In aspect (26), a glass-based article of any of aspects (15) to (25) is provided, wherein the center of the glass-based article comprises SnO₂.

In aspect (27), a glass-based article of any of aspects (15) to (25) is provided, wherein the center of the glass-based article comprises at least one of MgO, CaO, SrO, and BaO.

In aspect (28), a consumer electronic product is provided. The consumer electronic product comprises: a housing comprising a front surface, a back surface and side surfaces; electrical components at least partially within the housing, the electrical components comprising at least a controller, a memory, and a display, the display at or adjacent the front surface of the housing; and a cover substrate disposed over the display. At least a portion of at least one of the housing or the cover substrate comprises the glass-based article of any of aspects (15) to (27).

In aspect (29), a method is provided. The method comprises exposing a glass-based substrate to an environment with a relative humidity of greater than or equal to 75% to form a glass-based article with a compressive stress layer extending from a surface of the glass-based article to a depth of compression. The glass-based substrate is substantially free of alkali oxides; the depth of compression is greater than 5 μm, and the compressive stress layer comprises a compressive stress greater than or equal to 10 MPa.

In aspect (30), the method of aspect (29) is provided, wherein the relative humidity is 100%.

In aspect (31), the method of aspect (29) or (30) is provided, wherein the environment has a pressure greater than or equal to 0.1 MPa.

In aspect (32), the method of any of aspects (29) to (31) is provided, wherein the glass-based substrate has a coefficient of thermal expansion of less than 10 ppm.

In aspect (33), the method of any of aspects (29) to (32) is provided, wherein the glass-based substrate has a thickness of less than or equal to 2 mm.

In aspect (34), the method of any of aspects (29) to (33) is provided, wherein the glass-based substrate comprises greater than or equal to 2 mol % to less than or equal to 10 mol % P₂O₅.

In aspect (35), the method of any of aspects (29) to (34) is provided, wherein the glass-based substrate comprises greater than or equal to 15 mol % B₂O₃.

In aspect (36), the method of aspect (35) is provided, wherein the glass-based substrate is substantially free of P₂O₅.

In aspect (37), the method of any of aspects (29) to (36) is provided, wherein the glass-based substrate comprises SiO₂ and Al₂O₃.

In aspect (38), the method of any of aspects (29) to (37) is provided, wherein the glass-based substrate comprises SnO₂.

In aspect (39), the method of any of aspects (29) to (38) is provided, wherein the glass-based substrate comprises at least one of MgO, CaO, SrO, and BaO.

In aspect (40), the method of any of aspects (29) to (39) is provided, wherein the glass-based article comprises a hydrogen containing layer extending from the surface of the glass-based article to a depth of layer, wherein a hydrogen concentration of the hydrogen containing layer decreases from a maximum hydrogen concentration to the depth of layer.

In aspect (41), the method of any of aspects (29) to (40) is provided, wherein the compressive stress is greater than or equal to 100 MPa.

In aspect (42), the method of any of aspects (29) to (41) is provided, wherein the depth of compression is greater than or equal to 10 μm.

These and other aspects, advantages, and salient features will become apparent from the following detailed description, the accompanying drawings, and the appended claims.

### BRIEF DESCRIPTION OF THE DRAWINGS

FIG. 1 is a representation of a cross-section of a glass-based article according to an embodiment.

FIG. 2A is a plan view of an exemplary electronic device incorporating any of the glass-based articles disclosed herein.

FIG. 2B is a perspective view of the exemplary electronic device of FIG. 2A.

FIG. 3 is a schematic representation of various hydration front profiles according to an embodiment.

### DETAILED DESCRIPTION

In the following description, like reference characters designate like or corresponding parts throughout the several views shown in the figures. It is also understood that, unless otherwise specified, terms such as “top,” “bottom,” “outward,” “inward,” and the like are words of convenience and are not to be construed as limiting terms. Unless otherwise specified, a range of values, when recited, includes both the upper and lower limits of the range as well as any sub-ranges therebetween. As used herein, the indefinite articles “a,” “an,” and the corresponding definite article “the” mean “at least one” or “one or more,” unless otherwise specified. It also is understood that the various features disclosed in the specification and the drawings can be used in any and all combinations.

As used herein, the term “glass-based” is used in its broadest sense to include any objects made wholly or partly of glass, including glass ceramics (which include a crystalline phase and a residual amorphous glass phase). Unless otherwise specified, all compositions of the glasses described herein are expressed in terms of mole percent (mol %), and the constituents are provided on an oxide basis. Unless otherwise specified, all temperatures are expressed in terms of degrees Celsius (° C.).

It is noted that the terms “substantially” and “about” may be utilized herein to represent the inherent degree of uncertainty that may be attributed to any quantitative comparison, value, measurement, or other representation. These terms are also utilized herein to represent the degree by which a quantitative representation may vary from a stated reference without resulting in a change in the basic function of the subject matter at issue. For example, a glass that is “substantially free of K₂O” is one in which K₂O is not actively added or batched into the glass, but may be present in very small amounts as a contaminant, such as in amounts of less than about 0.01 mol %. As utilized herein, when the term “about” is used to modify a value, the exact value is also disclosed. For example, the term “greater than about 10 mol %” also discloses “greater than or equal to 10 mol %.”

Reference will now be made in detail to various embodiments, examples of which are illustrated in the accompanying examples and drawings.

The glass-based articles disclosed herein are formed by steam treating a glass-based substrate to produce a compresive stress layer exending from surface of the article to a depth of compression (DOC). The compressive stress layer includes a stress that decreases from a maximum stress to the depth of compression. In some embodiments, the maximum compressive stress may be located at the surface of the glass-based article. As used herein, depth of compression (DOC) means the depth at which the stress in the glass-based article changes from compressive to tensile. Thus, the glass-based article also contains a tensile stress region having a maximum central tension (CT), such that the forces within the glass-based article are balanced.

The glass-based articles further include a hydrogen-containing layer extending from a surface of the article to a depth of layer. The hydrogen-containing layer includes a hydrogen concentration that decreases from a maximum hydrogen concentration of the glass-based article to the depth of layer. In some embodiments, the maximum hydrogen concentration may be located at the surface of the glass-based article.

The glass-based articles may be formed by exposing glass-based substrates to environments containing water vapor, thereby allowing hydrogen species to penetrate the glass-based substrates and form the glass-based articles having a hydrogen-containing layer and/or a compressive stress layer. As utilized herein, hydrogen species includes molecular water, hydroxyl, hydrogen ions, and hydronium. The composition of the glass-based substrates may be selected to promote the interdiffusion of hydrogen species into the glass. As utilized herein, the term “glass-based substrate” refers to the precursor prior to exposure to a water vapor containing environment for the formation of a glass-based article that includes hydrogen-containing layers and/or compressive stress layers. Similarly, the term “glass-based article” refers to the post exposure article that includes a hydrogen-containing layer and/or a compressive stress layer.

The glass-based articles disclosed herein may exhibit a compressive stress layer without undergoing conventional ion exchange, thermal tempering, or lamination treatments. Ion exchange processes produces significant waste in the form of expended molten salt baths that require costly disposal, and also are applicable to only some glass compositions. Thermal tempering requires thich glass specimens as a practical matter, as thermal tempering of thin sheets utilizes small air gap quenching processes which results in sheet scratching damage that reduces performance and yeld. Additionally, it is difficult to achieve uniform compressive stress across surface and edge regions when thermal tempering thin glass sheets. Laminate processes result in exposed tensile stress regions when large sheets are cut to usable sizes, which is undesirable.

The water vapor treatment utilized to form the glass-based articles allows for reduced waste and lower cost when compared to ion exchange treatments as molten salts are not utilized, and alkali-free glass-based substrates may be employed. The water vapor treatment is also capable of strengthening thin (<2 mm) low-cost glass that would not be suitable for thermal tempering at such thicknesses. Additionally, the water vapor treatment may be performed at the part level, avoiding the undesirable exposed tensile stress regions associated with laminate processes. In sum, the glass-based articles disclosed herein may be produced with a low thickness and at a low cost while exhibiting a high compressive stress and deep depth of compression.

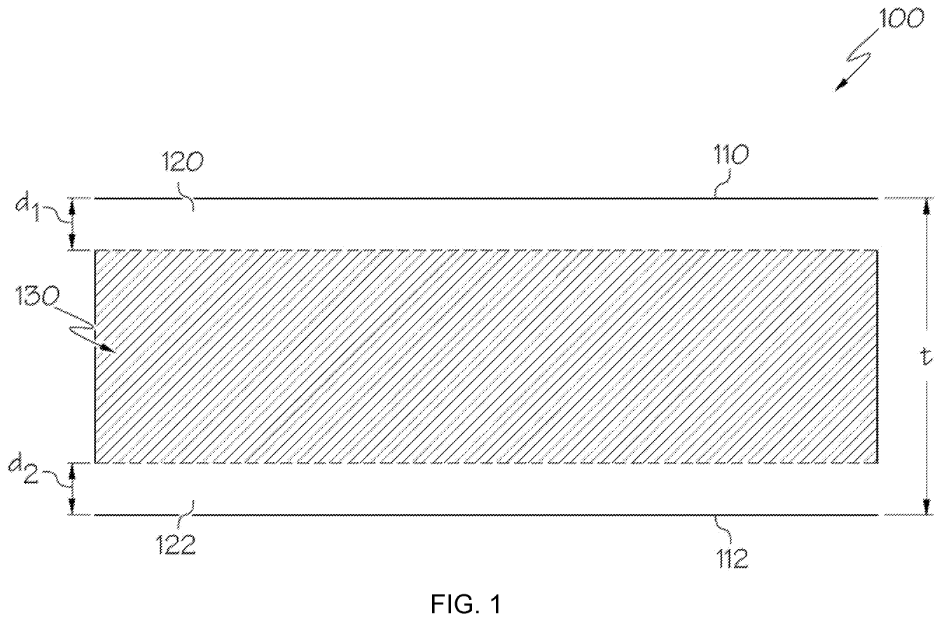

A representative cross-section of a glass-based article 100 according to some embodiments is depicted in FIG. 1. The glass-based article 100 has a thickness t that extends between a first surface 110 and a second surface 112. A first compressive stress layer 120 extends from the first surface 110 to a first depth of compression, where the first depth of compression has a depth d₁ measured from the first surface 110 into the glass-based article 100. A second compressive stress layer 122 extends from the second surface 112 to a second depth of compression, where the second depth of compression has a depth d₂ measured from the second surface 112 into the glass-based article 100. A tensile stres region 130 is present between the first depth of compression and the second depth of compression. In embodiments, the first depth of compression d₁ may be substantially equivalent or equivalent to the second depth of compression d₂.

In some embodiments, the compressive stress layer of the glass-based article may include a compressive stress of at greater than or equal to 10 MPa, such as greater than or equal to 20 MPa, greater than or equal to 30 MPa, greater than or equal to 40 MPa, greater than or equal to 50 MPa, greater than or equal to 60 MPa, greater than or equal to 70 MPa, greater than or equal to 80 MPa, greater than or equal to 90 MPa, greater than or equal to 100 MPa, greater than or equal to 110 MPa, greater than or equal to 120 MPa, greater than or equal to 130 MPa, greater than or equal to 140 MPa, greater than or equal to 145 MPa, greater than or equal to 150 MPa, greater than or equal to 160 MPa, greater than or equal to 170 MPa, greater than or equal to 180 MPa, greater than or equal to 190 MPa, greater than or equal to 200 MPa, greater than or equal to 210 MPa, greater than or equal to 220 MPa, greater than or equal to 230 MPa, greater than or equal to 240 MPa, greater than or equal to 250 MPa, greater than or equal to 260 MPa, greater than or equal to 270 MPa, greater than or equal to 280 MPa, greater than or equal to 290 MPa, or more. In some embodiments, the compressive stress layer may include a compressive stress of from greater than or equal to 10 MPa to less than or equal to 300 MPa, such as from greater than or equal to 20 MPa to less than or equal to 290 MPa, from greater than or equal to 20 MPa to less than or equal to 280 MPa, from greater than or equal to 30 MPa to less than or equal to 270 MPa, from greater than or equal to 40 MPa to less than or equal to 260 MPa, from greater than or equal to 50 MPa to less than or equal to 250 MPa, from greater than or equal to 60 MPa to less than or equal to 240 MPa, from greater than or equal to 70 MPa to less than or equal to 230 MPa, from greater than or equal to 80 MPa to less than or equal to 220 MPa, from greater than or equal to 90 MPa to less than or equal to 210 MPa, from greater than or equal to 100 MPa to less than or equal to 200 MPa, from greater than or equal to 110 MPa to less than or equal to 190 MPa, from greater than or equal to 120 MPa to less than or equal to 180 MPa, from greater than or equal to 130 MPa to less than or equal to 170 MPa, from greater than or equal to 140 MPa to less than or equal to 160 MPa, 150 MPa, or any sub-ranges formed from any of these endpoints.

In some embodiments, the DOC of the compressive stress layer may be greater than or equal to 5 μm, such as greater than or equal to 7 μm, greater than or equal to 10 μm, greater than or equal to 15 μm, greater than or equal to 20 μm, greater than or equal to 25 μm, greater than or equal to 30 μm, greater than or equal to 35 μm, greater than or equal to 40 μm, greater than or equal to 45 μm, greater than or equal to 50 μm, greater than or equal to 55 μm, greater than or equal to 60 μm, greater than or equal to 65 μm, greater than or equal to 70 μm, greater than or equal to 75 μm, greater than or equal to 80 μm, greater than or equal to 85 μm, greater than or equal to 90 μm, greater than or equal to 95 μm, or more. In some embodiments, the DOC of the compressive stress layer may be from greater than or equal to 5 μm to less than or equal to 100 μm, such as from greater than or equal to 7 μm to less than or equal to 95 μm, from greater than or equal to 10 μm to less than or equal to 90 μm, from greater than or equal to 15 μm to less than or equal to 85 μm, from greater than or equal to 20 μm to less than or equal to 80 μm, from greater than or equal to 25 μm to less than or equal to 75 μm, from greater than or equal to 30 μm to less than or equal to 70 μm, from greater than or equal to 35 μm to less than or equal to 65 μm, from greater than or equal to 40 μm to less than or equal to 60 μm, from greater than or equal to 45 μm to less than or equal to 55 μm, 50 μm, or any sub-ranges that may be formed from any of these endpoints.

In some embodiments, the glass-based articles may have a DOC greater than or equal to 0.05t, wherein t is the thickness of the glass-based article, such as greater than or equal to 0.06t, greater than or equal to 0.07t, greater than or equal to 0.08t, greater than or equal to 0.09t, greater than or equal to 0.10t, greater than or equal to 0.11t, greater than or equal to 0.12t, greater than or equal to 0.13t, greater than or equal to 0.14t, greater than or equal to 0.15t, greater than or equal to 0.16t, greater than or equal to 0.17t, greater than or equal to 0.18t, greater than or equal to 0.19t, or more. In some embodiments, the glass-based articles may have a DOC from greater than or equal to 0.05t to less than or equal to 0.20t, such as from greater than or equal to 0.06t to less than or equal to 0.19t, from greater than or equal to 0.07t to less than or equal to 0.18t, from greater than or equal to 0.08t to less than or equal to 0.17t, from greater than or equal to 0.09t to less than or equal to 0.16t, from greater than or equal to 0.10t to less than or equal to 0.15t, from greater than or equal to 0.11t to less than or equal to 0.14t, from greater than or equal to 0.12t to less than or equal to 0.13t, or any sub-ranges formed from any of these endpoints.

Compressive stress (including surface CS) is measured by surface stress meter using commercially available instruments such as the FSM-6000 (FSM), manufactured by Orihara Industrial Co., Ltd. (Japan). Surface stress measurements rely upon the accurate measurement of the stress optical coefficient (SOC), which is related to the birefringence of the glass. SOC in turn is measured according to Procedure C (Glass Disc Method) described in ASTM standard C770-16, entitled “Standard Test Method for Measurement of Glass Stress-Optical Coefficient,” the contents of which are incorporated herein by reference in their entirety. DOC is measured by FSM. The maximum central tension (CT) values are measured using a scattered light polariscope (SCALP) technique known in the art.

The hydrogen-containing layer of the glass-based articles may have a depth of layer (DOL) greater than 5 μm. In some embodiments, the depth of layer may be greater than or equal to 10 μm, such as greater than or equal to 15 μm, greater than or equal to 20 μm, greater than or equal to 25 μm, greater than or equal to 30 μm, greater than or equal to 35 μm, greater than or equal to 40 μm, greater than or equal to 45 μm, greater than or equal to 50 μm, greater than or equal to 55 μm, greater than or equal to 60 μm, greater than or equal to 65 μm, greater than or equal to 70 μm, greater than or equal to 75 μm, greater than or equal to 80 μm, greater than or equal to 85 μm, greater than or equal to 90 μm, greater than or equal to 95 μm, or more. In some embodiments, the depth of layer may be from greater than 5 μm to less than or equal to 100 μm, such as from greater than or equal to 10 μm to less than or equal to 95 μm, from greater than or equal to 15 μm to less than or equal to 90 μm, from greater than or equal to 20 μm to less than or equal to 85 μm, from greater than or equal to 25 μm to less than or equal to 80 μm, from greater than or equal to 30 μm to less than or equal to 75 μm, from greater than or equal to 35 μm to less than or equal to 70 μm, from greater than or equal to 40 μm to less than or equal to 65 μm, from greater than or equal to 45 μm to less than or equal to 60 μm, from greater than or equal to 50 μm to less than or equal to 55 μm, or any sub-ranges formed by any of these endpoints. In general, the depth of layer exhibited by the glass-based articles is greater than the depth of layer that may be produced by exposure to the ambient environment.

The hydrogen-containing layer of the glass-based articles may have a depth of layer (DOL) greater than 0.005t, wherein t is the thickness of the glass-based article. In some embodiments, the depth of layer may be greater than or equal to 0.010t, such as greater than or equal to 0.015t, greater than or equal to 0.020t, greater than or equal to 0.025t, greater than or equal to 0.030t, greater than or equal to 0.035t, greater than or equal to 0.040t, greater than or equal to 0.045t, greater than or equal to 0.050t, greater than or equal to 0.055t, greater than or equal to 0.060t, greater than or equal to 0.065t, greater than or equal to 0.070t, greater than or equal to 0.075t, greater than or equal to 0.080t, greater than or equal to 0.085t, greater than or equal to 0.090t, greater than or equal to 0.095t, greater than or equal to 0.10t, greater than or equal to 0.15t, greater than or equal to 0.20t, or more. In some embodiments, the DOL may be from greater than 0.005t to less than or equal to 0.205t, such as from greater than or equal to 0.010t to less than or equal to 0.200t, from greater than or equal to 0.015t to less than or equal to 0.195t, from greater than or equal to 0.020t to less than or equal to 0.190t, from greater than or equal to 0.025t to less than or equal to 0.185t, from greater than or equal to 0.030t to less than or equal to 0.180t, from greater than or equal to 0.035t to less than or equal to 0.175t, from greater than or equal to 0.040t to less than or equal to 0.170t, from greater than or equal to 0.045t to less than or equal to 0.165t, from greater than or equal to 0.050t to less than or equal to 0.160t, from greater than or equal to 0.055t to less than or equal to 0.155t, from greater than or equal to 0.060t to less than or equal to 0.150t, from greater than or equal to 0.065t to less than or equal to 0.145t, from greater than or equal to 0.070t to less than or equal to 0.140t, from greater than or equal to 0.075t to less than or equal to 0.135t, from greater than or equal to 0.080t to less than or equal to 0.130t, from greater than or equal to 0.085t to less than or equal to 0.125t, from greater than or equal to 0.090t to less than or equal to 0.120t, from greater than or equal to 0.095t to less than or equal to 0.115t, from greater than or equal to 0.100t to less than or equal to 0.110t, or any sub-ranges formed by any of these endpoints.

The depth of layer and hydrogen concentration are measured by a secondary ion mass spectrometry (SIMS) technique that is known in the art. The SIMS technique is capable of measuring the hydrogen concentration at a given depth, but is not capable of distinguishing the hydrogen species present in the glass-based article. For this reason, all hydrogen species contribute to the SIMS measured hydrogen concentration. As utilized herein, the depth of layer (DOL) refers to the first depth below the surface of the glass-based article where the hydrogen concentration is equal to the hydrogen concentration at the center of the glass-based article. This definition accounts for the hydrogen concentration of the glass-based substrate prior to treatment, such that the depth of layer refers to the depth of the hydrogen added by the treatment process. As a practical matter, the hydrogen concentration at the center of the glass-based article may be approximated by the hydrogen concentration at the depth from the surface of the glass-based article where the hydrogen concentration becomes substantially constant, as the hydrogen concentration is not expected to change between such a depth and the center of the glass-based article. This approximation allows for the determination of the DOL without measuring the hydrogen concentration throughout the entire depth of the glass-based article.

Without wishing to be bound by any particular theory, the hydrogen-containing layer of the glass-based articles may be the result of an interdiffusion of hydrogen species for ions contained in the compositions of the glass-based substrate. Hydrogen-containing species, such as H₃O⁺, H₂O, and/or H⁺, may diffuse into the glass-based substrate to form the glass-based article. Water could penetrate the glass-based substrates by forming silanol groups, breaking the network structure and causing a volume expansion of the glass. Such a volume expansion may generate a compressive stress layer in the glass-based articles. The compressive stress and depth of compression of the compressive stress layer may depend on the composition of the glass-based substrate utilized to form the glass-based article, and the water vapor treatment conditions, such as temperature, pressure, water content, and duration. The stress profile of the glass-based articles produced by the water vapor treatment may be similar to stress profiles produced by potassium for sodium ion exchange strengthening processes.

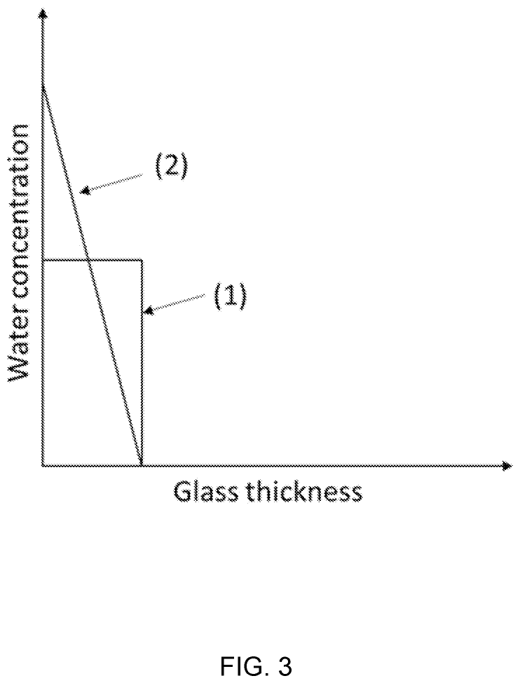

The glass-based articles that have compressive stress layers also exhibit weight gain when compared to the glass-based substrates prior to the water vapor treatment process. The water content of the hydrogen containing layer formed in the glass-based article by the water vapor treatment process may be estimated according to the below equation, with the assumption that the hydration front follows a step profile:

$${C}_{w} = \frac{W}{A} \frac{1}{DOL} \frac{1}{ρ}$$

where C_{w} is the water content in grams of water per gram of glass, W is the weight increase of the glass-based article in grams, A is the surface area of the glass-based article, DOL is expressed in centimeters, and p is the density of the glass. A step profile hydration front 1 is illustrated in FIG. 3. G may be converted to weight percent of water in the hydrogen containing layer by dividing this value by 1+C_{w}. If a linear profile hydration front 2 is assumed, the water concentration in the near surface region would be almost double the water concentration for a step profile 1, as shown in FIG. 3.

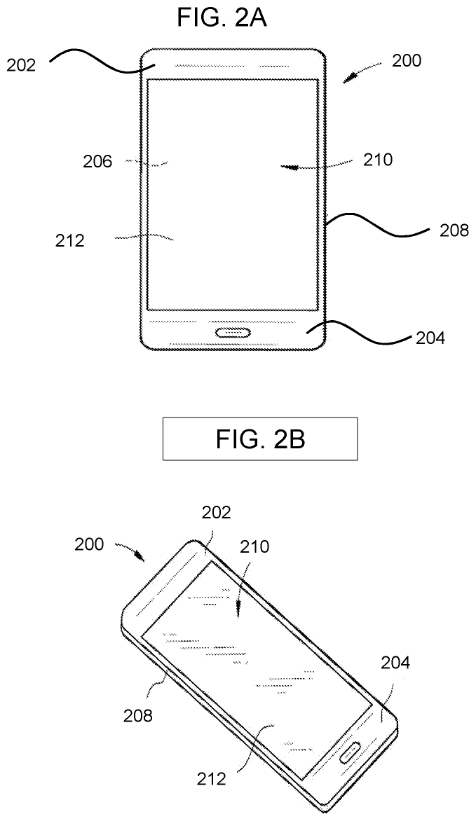

The glass-based articles disclosed herein may be incorporated into another article such as an article with a display (or display articles) (e.g., consumer electronics, including mobile phones, tablets, computers, navigation systems, wearable devices (e.g., watches) and the like), architectural articles, transportation articles (e.g., automotive, trains, aircraft, sea craft, etc.), appliance articles, or any article that requires some transparency, scratch-resistance, abrasion resistance or a combination thereof. An exemplary article incorporating any of the glass-based articles disclosed herein is shown in FIGS. 2A and 2B. Specifically, FIGS. 2A and 2B show a consumer electronic device 200 including a housing 202 having front 204, back 206, and side surfaces 208; electrical components (not shown) that are at least partially inside or entirely within the housing and including at least a controller, a memory, and a display 210 at or adjacent to the front surface of the housing; and a cover substrate 212 at or over the front surface of the housing such that it is over the display. In some embodiments, at least a portion of at least one of the cover substrate 212 and the housing 202 may include any of the glass-based articles disclosed herein.

The glass-based articles may be formed from glass-based substrates having any appropriate composition. The composition of the glass-based substrate may be specifically selected to promote the diffusion of hydrogen-containing species, such that a glass-based article including a hydrogen-containing layer and a compressive stress layer may be formed efficiently. The glass-based substrates are substantially free or free of alkali metal oxides. The use of glass-based substrates that are substantially free of alkali metal oxides allows the glass-based articles to be employed in applications such as semi-conductor or display related products where alklai cations may migrate into electronic components and “poison” transistors. In some embodiments, the glass-based substrates may have a composition that includes SiO₂, Al₂O₃, and P₂O₅. In some embodiments, the hydrogen species does not diffuse to the center of the glass-based article. Stated differently, the center of the glass-based article is the area least affected by the water vapor treatment. For this reason, the center of the glass-based article may have a composition that is substantially the same, or the same, as the composition of the glass-based substrate prior to treatment in the water containing environment.

In some embodiments, the glass-based substrates may have a coefficient of thermal expansion (CTE) lower than CTEs that generally allow for thermal tempering. In embodiments, the glass-based substrates may have a CTE of less than or equal to 10 ppm, such as less than or equal to 9 ppm, less than or equal to 8 ppm, less than or equal to 7 ppm, less than or equal to 6 ppm, less than or equal to 5 ppm, less than or equal to 4 ppm, less than or equal to 3 ppm, or less. In some embodiments, the glass-based substrate may have a CTE in a range from greater than or equal to 2 ppm to less than or equal to 10 ppm, such as from greater than or equal to 3 ppm to less than or equal to 9 ppm, from greater than or equal to 4 ppm to less than or equal to 8 ppm, from greater than or equal to 5 ppm to less than or equal to 7 ppm, 6 ppm, and any and all sub-ranges formed from any of these endpoints. The linear coefficient of thermal expansion (CTE) over the temperature range 25° C. to 300° C. is expressed in terms of 10⁻⁷/° C. and was determined using a push-rod dilatometer in accordance with ASTM E228-11.

The glass-based substrate may include any appropriate amount of SiO₂. SiO₂ is the largest constituent and, as such, SiO₂ is the primary constituent of the glass network formed from the glass composition. If the concentration of SiO₂ in the glass composition is too high, the formability of the glass composition may be diminished as higher concentrations of SiO₂ increase the difficulty of melting the glass, which, in turn, adversely impacts the formability of the glass. In some embodiments, the glass-based substrate may include SiO₂ in an amount from greater than or equal to 50 mol % to less than or equal to 72 mol %, such as from greater than or equal to 52 mol % to less than or equal to 70 mol %, from greater than or equal to 54 mol % to less than or equal to 68 mol %, from greater than or equal to 56 mol % to less than or equal to 66 mol %, from greater than or equal to 58 mol % to less than or equal to 64 mol %, from greater than or equal to 60 mol % to less than or equal to 62 mol %, or any sub-ranges formed by any of these endpoints.

The glass-based substrate may include any appropriate amount of Al₂O₃. Al₂O₃ may serve as a glass network former, similar to SiO₂. Al₂O₃ may increase the viscosity of the glass composition due to its tetrahedral coordination in a glass melt formed from a glass composition, decreasing the formability of the glass composition when the amount of Al₂O₃ is too high. However, when the concentration of Al₂O₃ is balanced against the concentration of SiO₂ and the concentration of alkali oxides in the glass composition, Al₂O₃ can reduce the liquidus temperature of the glass melt, thereby enhancing the liquidus viscosity and improving the compatibility of the glass composition with certain forming processes, such as the fusion forming process. The inclusion of Al₂O₃ in the glass-based substrate prevents phase separation and reduces the number of non-bridging oxygens (NBOs) in the glass. Additionally, Al₂O₃ can improve the effectiveness of ion exchange. In some embodiments, the glass-based substrate may include Al₂O₃ in an amount of from greater than or equal to 1 mol % to less than or equal to 25 mol %, such as from greater than or equal to 2 mol % to less than or equal to 23 mol %, from greater than or equal to 3 mol % to less than or equal to 21 mol %, from greater than or equal to 4 mol % to less than or equal to 20 mol %, from greater than or equal to 5 mol % to less than or equal to 19 mol %, from greater than or equal to 6 mol % to less than or equal to 17 mol %, from greater than or equal to 7 mol % to less than or equal to 15 mol %, from greater than or equal to 8 mol % to less than or equal to 14 mol %, from greater than or equal to 9 mol % to less than or equal to 13 mol %, from greater than or equal to 10 mol % to less than or equal to 12 mol %, 11 mol %, or any sub-ranges formed by any of these endpoints.

The glass-based substrate may include any amount of P₂O₅ sufficient to produce the desired hydrogen diffusivity. The inclusion of phosphorous in the glass-based substrate promotes faster interdiffusion. Thus, the phosphorous containing glass-based substrates allow the efficient formation of glass-based articles including a hydrogen-containing layer. The inclusion of P₂O₅ also allows for the production of a glass-based article with a deep depth of layer (e.g., greater than about 10 μm) in a relatively short treatment time. In some embodiments, the glass-based substrate may include P₂O₅ in an amount of from greater than or equal to 0 mol % to less than or equal to 15 mol %, such as from greater than or equal to 1 mol % to less than or equal to 14 mol %, from greater than or equal to 2 mol % to less than or equal to 13 mol %, from greater than or equal to 3 mol % to less than or equal to 12 mol %, from greater than or equal to 4 mol % to less than or equal to 11 mol %, from greater than or equal to 5 mol % to less than or equal to 10 mol %, from greater than or equal to 6 mol % to less than or equal to 9 mol %, from greater than or equal to 7 mol % to less than or equal to 8 mol %, or any sub-ranges formed by any of these endpoints. In some embodiments, the glass-based substrate may include P₂O₅ in an amount of from greater than or equal to 2 mol % to less than or equal to 10 mol %, such as from greater than or equal to 5 mol % to less than or equal to 10 mol %. In embodiments, the glass-based substrate may be substantially free or free of P₂O₅. More specifically, in some embodiments where B₂O₃ is present in the glass-based substrates in high amounts, greater than or equal to 15 mol %, the glass-based substrate may be substantially free or free of P₂O₅.

The glass-based substrate may additionally include B₂O₃. The inclusion of B₂O₃ in the glass-based substrates may increase the damage resistance of the glass-based substrates, and thereby increase the damage resistance of the glass-based articles formed therefrom. In some emdbodiments, the glass-based susbtrates may include B₂O₃ in an amount from greater than or equal to 0 mol % to less than or equal to 30 mol %, such as from greater than or equal to 1 mol % to less than or equal to 28 mol %, from greater than or equal to 2 mol % to less than or equal to 26 mol %, from greater than or equal to 3 mol % to less than or equal to 25 mol %, from greater than or equal to 4 mol % to less than or equal to 24 mol %, from greater than or equal to 5 mol % to less than or equal to 23 mol %, from greater than or equal to 6 mol % to less than or equal to 22 mol %, from greater than or equal to 7 mol % to less than or equal to 21 mol %, from greater than or equal to 8 mol % to less than or equal to 20 mol %, from greater than or equal to 9 mol % to less than or equal to 19 mol %, from greater than or equal to 10 mol % to less than or equal to 18 mol %, from greater than or equal to 11 mol % to less than or equal to 17 mol %, from greater than or equal to 12 mol % to less than or equal to 16 mol %, from greater than or equal to 13 mol % to less than or equal to 15 mol %, 14 mol %, or any and all sub-ranges formed from these endpoints. In some embodiments, the glass-based substrates may contain greater than or equal to 15 mol % B₂O₃. In embodiments, the glass-based substrates may be substantially free or free of B₂O₃.

The glass-based substrate may additionally include MgO. In some embodiments, the glass-based substrates may include MgO in an amount from greater than or equal to 0 mol % to less than or equal to 3 mol %, such as from greater than or equal to 1 mol % to less than or equal to 2 mol %, or any and all sub-ranges formed from these endpoints. In embodiments, the glass-based substrates may be substantially free or free of MgO.

The glass-based substrate may additionally include CaO. In some embodiments, the glass-based substrates may include CaO in an amount from greater than or equal to 0 mol % to less than or equal to 8 mol %, such as from greater than or equal to 1 mol % to less than or equal to 7 mol %, from greater than or equal to 2 mol % to less than or equal to 6 mol %, from greater than or equal to 3 mol % to less than or equal to 5 mol %, 4 mol %, or any and all sub-ranges formed from these endpoints. In embodiments, the glass-based substrates may be substantially free or free of CaO.

The glass-based substrate may additionally include SrO. In some embodiments, the glass-based substrates may include SrO in an amount from greater than or equal to 0 mol % to less than or equal to 7 mol %, such as from greater than or equal to 1 mol % to less than or equal to 6 mol %, from greater than or equal to 2 mol % to less than or equal to 5 mol %, %, from greater than or equal to 3 mol % to less than or equal to 4 mol %, or any and all sub-ranges formed from these endpoints. In embodiments, the glass-based substrates may be substantially free or free of SrO.

In some embodiments, the glass-based substrate may include at least one of MgO, CaO, SrO, and BaO. In embodiments, the glass-based substrate contains BaO. In other embodiments, the glass-based substrate is substantially free of free of BaO.

The glass-based substrates may additionally include ZrO₂. In some embodiments, the glass-based substrate may be substantially free or free of ZrO₂.

The glass-based substrates may additionally include a fining agent. In some embodiments, the fining agent may include tin. In embodiments, the glass-based susbstrate may include SnO₂ in an amount from greater than or equal to 0 mol % to less than or equal to 0.5 mol %, such as from greater than 0 mol % to less than or equal to 0.1 mol %. In embodiments, the glass-based substrate may be substabtially free or free of SnO₂.

The glass-based substrate may have any appropriate geometry. In some embodiments, the glass-based substrate may have a thickness of less than or equal to 2 mm, such as less than or equal to 1.9 mm, less than or equal to 1.8 mm, less than or equal to 1.7 mm, less than or equal to 1.6 mm, less than or equal to 1.5 mm, less than or equal to 1.4 mm, less than or equal to 1.3 mm, less than or equal to 1.2 mm, less than or equal to 1.1 mm, less than or equal to 1 mm, less than or equal to 900 μm, less than or equal to 800 μm, less than or equal to 700 μm, less than or equal to 600 μm, less than or equal to 500 μm, less than or equal to 400 μm, less than or equal to 300 μm, or less. In embodiments, the glass-based substrate may have a thickness from greater than or equal to 300 μm to less than or equal to 2 mm, such as from greater than or equal to 400 μm to less than or equal to 1.9 mm, from greater than or equal to 500 μm to less than or equal to 1.8 mm, from greater than or equal to 600 μm to less than or equal to 1.7 mm, from greater than or equal to 700 μm to less than or equal to 1.6 mm, from greater than or equal to 800 μm to less than or equal to 1.5 mm, from greater than or equal to 900 μm to less than or equal to 1.4 mm, from greater than or equal to 1 mm to less than or equal to 1.3 mm, from greater than or equal to 1.1 mm to less than or equal to 1.2 mm, or any and all sub-ranges formed from these endpoints. In some embodiments, the glass-based substrate may have be plate or sheet shaped. In some other embodiments, the glass-based substrates may have a 2.5D or 3D shape. As utilized herein, a “2.5D shape” refers to a sheet shaped article with at least one major surface being at least partially nonplanar, and a second major surface being substantially planar. As utilized herein, a “3D shape” refers to an article with first and second opposing major surfaces that are at least partially nonplanar. The glass-based articles may have dimensions and shapes substantially similar or the same as the glass-based substrates from which they are formed.

The glass-based articles may be produced from the glass-based substrate by exposure to water vapor under any appropriate conditions. The exposure may be carried out in any appropriate device, such as a furnace with relative humidity control. The exposure may also be carried out at an elevated pressure, such as a furnace or autoclave with relative humidity and pressure control.

In one embodiment, the glass-based articles may be produced by exposing a glass-based substrate to an environment with a pressure greater than ambient pressure and containing water vapor. The environment may have a pressure greater than 0.1 MPa and a water partial pressure of greater than or equal to 0.075 MPa. The elevated pressure allows in the exposure environment allows for a higher concentration of water vapor in the environment, especially as temperatures are increased. As the temperature increases the amount of water available for diffusion into the glass-based substrates to form glass-based articles decreases for a fixed volume, such as the interior of a furnace or autoclave. Thus, while increasing the temperature of the water vapor treatment environment may increase the rate of diffusion of hydrogen species into the glass-based substrate, reduced total water vapor concentration and stress relaxation at higher temperatures produce decreased compressive stress when pressure is constant. As temperatures increase, such as those above the atmospheric pressure saturation condition, applying increased pressure to reach the saturation condition increases the concentration of water vapor in the environment significantly.

In some embodiments, the glass-based substrates may be exposed to an environment at a pressure greater than 0.1 MPa, such as greater than or equal to 0.2 MPa, greater than or equal to 0.3 MPa, greater than or equal to 0.4 MPa, greater than or equal to 0.5 MPa, greater than or equal to 0.6 MPa, greater than or equal to 0.7 MPa, greater than or equal to 0.8 MPa, greater than or equal to 0.9 MPa, greater than or equal to 1.0 MPa, greater than or equal to 1.1 MPa, greater than or equal to 1.2 MPa, greater than or equal to 1.3 MPa, greater than or equal to 1.4 MPa, greater than or equal to 1.5 MPa, greater than or equal to 1.6 MPa, greater than or equal to 1.7 MPa, greater than or equal to 1.8 MPa, greater than or equal to 1.9 MPa, greater than or equal to 2.0 MPa, greater than or equal to 2.1 MPa, greater than or equal to 2.2 MPa, greater than or equal to 2.3 MPa, greater than or equal to 2.4 MPa, greater than or equal to 2.5 MPa, greater than or equal to 2.6 MPa, greater than or equal to 2.7 MPa, greater than or equal to 2.8 MPa, greater than or equal to 2.9 MPa, greater than or equal to 3.0 MPa, greater than or equal to 3.1 MPa, greater than or equal to 3.2 MPa, greater than or equal to 3.3 MPa, greater than or equal to 3.4 MPa, greater than or equal to 3.5 MPa, greater than or equal to 1.6 MPa, greater than or equal to 3.7 MPa, greater than or equal to 3.8 MPa, greater than or equal to 3.9 MPa, greater than or equal to 4.0 MPa, greater than or equal to 4.1 MPa, greater than or equal to 4.2 MPa, greater than or equal to 4.3 MPa, greater than or equal to 4.4 MPa, greater than or equal to 4.5 MPa, greater than or equal to 4.6 MPa, greater than or equal to 4.7 MPa, greater than or equal to 4.8 MPa, greater than or equal to 4.9 MPa, greater than or equal to 5.0 MPa, greater than or equal to 5.1 MPa, greater than or equal to 5.2 MPa, greater than or equal to 5.3 MPa, greater than or equal to 5.4 MPa, greater than or equal to 5.5 MPa, greater than or equal to 5.6 MPa, greater than or equal to 5.7 MPa, greater than or equal to 5.8 MPa, greater than or equal to 5.9 MPa, greater than or equal to 6.0 MPa, or more. In embodiments, the glass-based substrates may be exposed to an environment at a pressure of from greater 0.1 MPa to less than or equal to 25 MPa, such as from greater than or equal to 0.2 MPa to less than or equal to 24 MPa, from greater than or equal to 0.3 MPa to less than or equal to 23 MPa, from greater than or equal to 0.4 MPa to less than or equal to 22 MPa, from greater than or equal to 0.5 MPa to less than or equal to 21 MPa, from greater than or equal to 0.6 MPa to less than or equal to 20 MPa, from greater than or equal to 0.7 MPa to less than or equal to 19 MPa, from greater than or equal to 0.8 MPa to less than or equal to 18 MPa, from greater than or equal to 0.9 MPa to less than or equal to 17 MPa, from greater than or equal to 1.0 MPa to less than or equal to 16 MPa, from greater than or equal to 1.1 MPa to less than or equal to 15 MPa, from greater than or equal to 1.2 MPa to less than or equal to 14 MPa, from greater than or equal to 1.3 MPa to less than or equal to 13 MPa, from greater than or equal to 1.4 MPa to less than or equal to 12 MPa, from greater than or equal to 1.5 MPa to less than or equal to 11 MPa, from greater than or equal to 1.6 MPa to less than or equal to 10 MPa, from greater than or equal to 1.7 MPa to less than or equal to 9 MPa, from greater than or equal to 1.8 MPa to less than or equal to 8 MPa, from greater than or equal to 1.9 MPa to less than or equal to 7 MPa, from greater than or equal to 1.9 MPa to less than or equal to 6.9 MPa, from greater than or equal to 2.0 MPa to less than or equal to 6.8 MPa, from greater than or equal to 2.1 MPa to less than or equal to 6.7 MPa, from greater than or equal to 2.2 MPa to less than or equal to 6.6 MPa, from greater than or equal to 2.3 MPa to less than or equal to 6.5 MPa, from greater than or equal to 2.4 MPa to less than or equal to 6.4 MPa, from greater than or equal to 2.5 MPa to less than or equal to 6.3 MPa, from greater than or equal to 2.6 MPa to less than or equal to 6.2 MPa, from greater than or equal to 2.7 MPa to less than or equal to 6.1 MPa, from greater than or equal to 2.8 MPa to less than or equal to 6.0 MPa, from greater than or equal to 2.9 MPa to less than or equal to 5.9 MPa, from greater than or equal to 3.0 MPa to less than or equal to 5.8 MPa, from greater than or equal to 3.1 MPa to less than or equal to 5.7 MPa, from greater than or equal to 3.2 MPa to less than or equal to 5.6 MPa, from greater than or equal to 3.3 MPa to less than or equal to 5.5 MPa, from greater than or equal to 3.4 MPa to less than or equal to 5.4 MPa, from greater than or equal to 3.5 MPa to less than or equal to 5.3 MPa, from greater than or equal to 3.6 MPa to less than or equal to 5.2 MPa, from greater than or equal to 3.7 MPa to less than or equal to 5.1 MPa, from greater than or equal to 3.8 MPa to less than or equal to 5.0 MPa, from greater than or equal to 3.9 MPa to less than or equal to 4.9 MPa, from greater than or equal to 4.0 MPa to less than or equal to 4.8 MPa, from greater than or equal to 4.1 MPa to less than or equal to 4.7 MPa, from greater than or equal to 4.2 MPa to less than or equal to 4.6 MPa, from greater than or equal to 4.3 MPa to less than or equal to 4.5 MPa, 4.4 MPa, or any and all sub-ranges formed from any of these endpoints.

In some embodiments, the glass-based substrates may be exposed to an environment with a water partial pressure greater than or equal to 0.075 MPa, such as greater than or equal to 0.1 MPa, greater than or equal to 0.2 MPa, greater than or equal to 0.3 MPa, greater than or equal to 0.4 MPa, greater than or equal to 0.5 MPa, greater than or equal to 0.6 MPa, greater than or equal to 0.7 MPa, greater than or equal to 0.8 MPa, greater than or equal to 0.9 MPa, greater than or equal to 1.0 MPa, greater than or equal to 1.1 MPa, greater than or equal to 1.2 MPa, greater than or equal to 1.3 MPa, greater than or equal to 1.4 MPa, greater than or equal to 1.5 MPa, greater than or equal to 1.6 MPa, greater than or equal to 1.7 MPa, greater than or equal to 1.8 MPa, greater than or equal to 1.9 MPa, greater than or equal to 2.0 MPa, greater than or equal to 2.1 MPa, greater than or equal to 2.2 MPa, greater than or equal to 2.3 MPa, greater than or equal to 2.4 MPa, greater than or equal to 2.5 MPa, greater than or equal to 2.6 MPa, greater than or equal to 2.7 MPa, greater than or equal to 2.8 MPa, greater than or equal to 2.9 MPa, greater than or equal to 3.0 MPa, greater than or equal to 3.1 MPa, greater than or equal to 3.2 MPa, greater than or equal to 3.3 MPa, greater than or equal to 3.4 MPa, greater than or equal to 3.5 MPa, greater than or equal to 1.6 MPa, greater than or equal to 3.7 MPa, greater than or equal to 3.8 MPa, greater than or equal to 3.9 MPa, greater than or equal to 4.0 MPa, greater than or equal to 4.1 MPa, greater than or equal to 4.2 MPa, greater than or equal to 4.3 MPa, greater than or equal to 4.4 MPa, greater than or equal to 4.5 MPa, greater than or equal to 4.6 MPa, greater than or equal to 4.7 MPa, greater than or equal to 4.8 MPa, greater than or equal to 4.9 MPa, greater than or equal to 5.0 MPa, greater than or equal to 5.1 MPa, greater than or equal to 5.2 MPa, greater than or equal to 5.3 MPa, greater than or equal to 5.4 MPa, greater than or equal to 5.5 MPa, greater than or equal to 5.6 MPa, greater than or equal to 5.7 MPa, greater than or equal to 5.8 MPa, greater than or equal to 5.9 MPa, greater than or equal to 6.0 MPa, greater than or equal to 7.0 MPa, greater than or equal to 8.0 MPa, greater than or equal to 9.0 MPa, greater than or equal to 10.0 MPa, greater than or equal to 11.0 MPa, greater than or equal to 12.0 MPa, greater than or equal to 13.0 MPa, greater than or equal to 14.0 MPa, greater than or equal to 15.0 MPa, greater than or equal to 16.0 MPa, greater than or equal to 17.0 MPa, greater than or equal to 18.0 MPa, greater than or equal to 19.0 MPa, greater than or equal to 20.0 MPa, greater than or equal to 21.0 MPa, greater than or equal to 22.0 MPa, or more. In embodiments, the glass-based substrates may be exposed to an environment with a water partial pressure from greater than or equal to 0.075 MPa to less than or equal to 22 MPa, such as from greater than or equal to 0.1 MPa to less than or equal to 21 MPa, from greater than or equal to 0.2 MPa to less than or equal to 20 MPa, from greater than or equal to 0.3 MPa to less than or equal to 19 MPa, from greater than or equal to 0.4 MPa to less than or equal to 18 MPa, from greater than or equal to 0.5 MPa to less than or equal to 17 MPa, from greater than or equal to 0.6 MPa to less than or equal to 16 MPa, from greater than or equal to 0.7 MPa to less than or equal to 15 MPa, from greater than or equal to 0.8 MPa to less than or equal to 14 MPa, from greater than or equal to 0.9 MPa to less than or equal to 13 MPa, from greater than or equal to 1.0 MPa to less than or equal to 12 MPa, from greater than or equal to 1.1 MPa to less than or equal to 11 MPa, from greater than or equal to 1.2 MPa to less than or equal to 10 MPa, from greater than or equal to 1.3 MPa to less than or equal to 9 MPa, from greater than or equal to 1.4 MPa to less than or equal to 8 MPa, from greater than or equal to 1.5 MPa to less than or equal to 7 MPa, from greater than or equal to 1.6 MPa to less than or equal to 6.9 MPa, from greater than or equal to 1.7 MPa to less than or equal to 6.8 MPa, from greater than or equal to 1.8 MPa to less than or equal to 6.7 MPa, from greater than or equal to 1.9 MPa to less than or equal to 6.6 MPa, from greater than or equal to 2.0 MPa to less than or equal to 6.5 MPa, from greater than or equal to 2.1 MPa to less than or equal to 6.4 MPa, from greater than or equal to 2.2 MPa to less than or equal to 6.3 MPa, from greater than or equal to 2.3 MPa to less than or equal to 6.2 MPa, from greater than or equal to 2.4 MPa to less than or equal to 6.1 MPa, from greater than or equal to 2.5 MPa to less than or equal to 6.0 MPa, from greater than or equal to 2.6 MPa to less than or equal to 5.9 MPa, from greater than or equal to 2.7 MPa to less than or equal to 5.8 MPa, from greater than or equal to 2.8 MPa to less than or equal to 5.7 MPa, from greater than or equal to 2.9 MPa to less than or equal to 5.6 MPa, from greater than or equal to 3.0 MPa to less than or equal to 5.5 MPa, from greater than or equal to 3.1 MPa to less than or equal to 5.4 MPa, from greater than or equal to 3.2 MPa to less than or equal to 5.3 MPa, from greater than or equal to 3.3 MPa to less than or equal to 5.2 MPa, from greater than or equal to 3.4 MPa to less than or equal to 5.1 MPa, from greater than or equal to 3.5 MPa to less than or equal to 5.0 MPa, from greater than or equal to 3.6 MPa to less than or equal to 4.9 MPa, from greater than or equal to 3.7 MPa to less than or equal to 4.8 MPa, from greater than or equal to 3.8 MPa to less than or equal to 4.7 MPa, from greater than or equal to 3.9 MPa to less than or equal to 4.6 MPa, from greater than or equal to 4.0 MPa to less than or equal to 4.5 MPa, from greater than or equal to 4.1 MPa to less than or equal to 4.4 MPa, from greater than or equal to 4.2 MPa to less than or equal to 4.3 MPa, or any and all sub-ranges formed from any of these endpoints.

In some embodiments, the glass-based substrates may be exposed to an environment with a relative humidity of greater than or equal to 75%, such as greater than or equal to 80%, greater than or equal to 85%, greater than or equal to 90%, greater than or equal to 95%, greater than or equal to 99%, or more. In some embodiments, the glass-based substrate may be exposed to an environment with 100% relative humidity.

In some embodiments, the glass-based substrates may be exposed to an environment at with a temperature of greater than or equal to 100° C., such as greater than or equal to 105° C., greater than or equal to 110° C., greater than or equal to 115° C., greater than or equal to 120° C., greater than or equal to 125° C., greater than or equal to 130° C., greater than or equal to 135° C., greater than or equal to 140° C., greater than or equal to 145° C., greater than or equal to 150° C., greater than or equal to 155° C., greater than or equal to 160° C., greater than or equal to 165° C., greater than or equal to 170° C., greater than or equal to 175° C., greater than or equal to 180° C., greater than or equal to 185° C., greater than or equal to 190° C., greater than or equal to 195° C., greater than or equal to 200° C., greater than or equal to 205° C., greater than or equal to 210° C., greater than or equal to 215° C., greater than or equal to 220° C., greater than or equal to 225° C., greater than or equal to 230° C., greater than or equal to 235° C., greater than or equal to 240° C., greater than or equal to 245° C., greater than or equal to 250° C., greater than or equal to 255° C., greater than or equal to 260° C., greater than or equal to 265° C., greater than or equal to 270° C., greater than or equal to 275° C., greater than or equal to 280° C., greater than or equal to 285° C., greater than or equal to 290° C., greater than or equal to 295° C., greater than or equal to 300° C., or more. In some embodiments, the glass-based substrates may be exposed to an environment with a temperature from greater than or equal to 100° C. to less than or equal to 400° C., such as from greater than or equal to 105° C. to less than or equal to 390° C., from greater than or equal to 110° C. to less than or equal to 380° C., from greater than or equal to 115° C. to less than or equal to 370° C., from greater than or equal to 120° C. to less than or equal to 360° C., from greater than or equal to 125° C. to less than or equal to 350° C., from greater than or equal to 130° C. to less than or equal to 340° C., from greater than or equal to 135° C. to less than or equal to 330° C., from greater than or equal to 140° C. to less than or equal to 320° C., from greater than or equal to 145° C. to less than or equal to 310° C., from greater than or equal to 150° C. to less than or equal to 300° C., from greater than or equal to 155° C. to less than or equal to 295° C., from greater than or equal to 160° C. to less than or equal to 290° C., from greater than or equal to 165° C. to less than or equal to 285° C., from greater than or equal to 170° C. to less than or equal to 280° C., from greater than or equal to 175° C. to less than or equal to 275° C., from greater than or equal to 180° C. to less than or equal to 270° C., from greater than or equal to 185° C. to less than or equal to 265° C., from greater than or equal to 190° C. to less than or equal to 260° C., from greater than or equal to 195° C. to less than or equal to 255° C., from greater than or equal to 200° C. to less than or equal to 250° C., from greater than or equal to 205° C. to less than or equal to 245° C., from greater than or equal to 210° C. to less than or equal to 240° C., from greater than or equal to 215° C. to less than or equal to 235° C., from greater than or equal to 220° C. to less than or equal to 230° C., 225° C., or any and all sub-ranges formed from any of these endpoints.

In some embodiments, the glass-based substrate may be exposed to the water vapor containing environment for a time period sufficient to produce the desired degree of hydrogen-containing species diffusion and the desired compressive stress layer. In some embodiments, the glass-based substrate may be exposed to the water vapor containing environment for greater than or equal to 2 hours, such as greater than or equal to 4 hours, greater than or equal to 6 hours, greater than or equal to 8 hours, greater than or equal to 10 hours, greater than or equal to 12 hours, greater than or equal to 14 hours, greater than or equal to 16 hours, greater than or equal to 18 hours, greater than or equal to 20 hours, greater than or equal to 22 hours, greater than or equal to 24 hours, greater than or equal to 30 hours, greater than or equal to 36 hours, greater than or equal to 42 hours, greater than or equal to 48 hours, greater than or equal to 54 hours, greater than or equal to 60 hours, greater than or equal to 66 hours, greater than or equal to 72 hours, greater than or equal to 78 hours, greater than or equal to 84 hours, greater than or equal to 90 hours, greater than or equal to 96 hours, greater than or equal to 102 hours, greater than or equal to 108 hours, greater than or equal to 114 hours, greater than or equal to 120 hours, greater than or equal to 126 hours, greater than or equal to 132 hours, greater than or equal to 138 hours, greater than or equal to 144 hours, greater than or equal to 150 hours, greater than or equal to 156 hours, greater than or equal to 162 hours, greater than or equal to 168 hours, or more. In some embodiments, the glass-based substrate may be exposed to the water vapor containing environment for a time period from greater than or equal to 2 hours to less than or equal to 10 days, such as from greater than or equal to 4 hours to less than or equal to 9 days, from greater than or equal to 6 hours to less than or equal to 8 days, from greater than or equal to 8 hours to less than or equal to 168 hours, from greater than or equal to 10 hours to less than or equal to 162 hours, from greater than or equal to 12 hours to less than or equal to 156 hours, from greater than or equal to 14 hours to less than or equal to 150 hours, from greater than or equal to 16 hours to less than or equal to 144 hours, from greater than or equal to 18 hours to less than or equal to 138 hours, from greater than or equal to 20 hours to less than or equal to 132 hours, from greater than or equal to 22 hours to less than or equal to 126 hours, from greater than or equal to 24 hours to less than or equal to 120 hours, from greater than or equal to 30 hours to less than or equal to 114 hours, from greater than or equal to 36 hours to less than or equal to 108 hours, from greater than or equal to 42 hours to less than or equal to 102 hours, from greater than or equal to 48 hours to less than or equal to 96 hours, from greater than or equal to 54 hours to less than or equal to 90 hours, from greater than or equal to 60 hours to less than or equal to 84 hours, from greater than or equal to 66 hours to less than or equal to 78 hours, 72 hours, or any and all sub-ranges formed from any of these endpoints.

In some embodiments, the glass-based substrates may be exposed to multiple water vapor containing environments. In embodiments, the glass-based substrate may be exposed to a first environment to form a first glass-based artice with a first compressive stress layer extending from a surface of the first glass-based article to a first depth of compression, and the first glass-based article may then be exposed to a second environment to form a second glass-based article with a second compressive stress layer extending from a surface of the second glass-based article to a second depth of compression. The first environment has a first water partial pressure and a first temperature, and the glass-based substrate is exposed to the first environment for a first time period. The second envrionment has a second water partial pressure and a second temperature, and the first glass-based article is exposed to the second environment for a second time period.

The first water partial pressure and the second water partial pressure may be any appropriate partial pressure, such as greater than or equal to 0.075 MPa. The first and second partial pressure may be any of the values disclosed herein with respect to the water partial pressures employed in the elevated pressure method. In embodiments, the first and second environments may have, independently, a relative humidity of greater than or equal to 75%, such as greater than or equal to 80%, greater than or equal to 90%, greater than or equal to 95%, or equal to 100%. In some embodiments, at least one of the first environment and the second environment has a relative humidity of 100%.

The first compressive stress layer includes a first maximum compressive stress, and the second compressive stress layer includes a second maximum compressive stress. In embodiments, the first maximum compressive stress is less than the second maximum compressive stress. The second maximum compressive stress may be compared to a compressive stress “spike” of the type formed through multi-step or mixed bath ion exchange techniques. The first and second maximum compressive stress may have any of the values disclosed herein with respect to the compressive stress of the glass-based article. In embodiments, the second maximum compressive stress may be greater than or equal to 50 MPa.

The first depth of compression may be less than or equal to the second depth of compression. In some embodiments, the first depth of compression is less than the second depth of compression. The first depth of compression and the second depth of compression may have any of the values disclosed herein with respect to the depth of compression. In embodiments, the second depth of compression is greater than 5 μm.

The first temperature may be greater than or equal to the second temperature. In embodiments, the first temperature is greater than the second temperature. The first and second temperatures may be any of the temperatures disclosed in connection with the elevated pressure method.

The first time period may be less than or equal to the second time period. In embodiments, the first time period is less than the second time period. The first and second time periods may be any of the time periods disclosed in connection with the elevated pressure method.

In embodiments, any or all of the multiple exposures to a water vapor containing environment may be performed at an elevated pressure. For example, at least one of the first environment and the second environment may have a pressure greater than 0.1 MPa. The first and second environments may have any pressure disclosse in connection with the elevated pressure method.

In some embodiments, the multiple water vapor environment exposure technique may include more than two exposure environments. In embodiments, the second glass-based article may be exposed to a third environment to form a third glass-based article. The third environment has a third water partial pressure and a third temperature, and the second glass-based article is exposed to the third environment for a third time period. The third glass-based article includes a third compressive stress layer extending from a surface of the article to a third depth of compression and having a third maximum compressive stress. The third water partial pressure may be greater than or equal to 0.075 MPa. The values of any of the properties of the third environment and third glass-based article may be selected from those disclosed for the corresponding properties in connection with the elevated pressure method.

In some embodiments, the first glass-based article may be cooled to ambient temperature or otherwise removed from the first environment after the conclusion of the first time period and prior to being exposed to the second environment. In some embodiments, the first glass-based article may remain in the first environment after the conclusion of the first time period, and the first environment conditions may be changed to the second environment conditions without cooling to ambient temperature or removing the first glass-based article from the water vapor containing enviroment.

The methods of producing the glass-based articles disclosed herein may be free of an ion exchange treatment with an alkali ion source. In embodiments, the glass-based articles are produced by methods that do not include an ion exchange with an alkali ion source.

The exposure conditions may be modified to reduce the time necessary to produce the desired amount of hydrogen-containing species diffusion into the glass-based substrate. For example, the temperature and/or relative humidity may be increased to reduce the time required to achieve the desired degree of hydrogen-containing species diffusion and depth of layer into the glass-based substrate.

### Exemplary Embodiments

Alkali-free glass compositions that are particularly suited for formation of the glass-based articles described herein were formed into glass-based substrates, and the glass compositions are provided in Table I below. The density of the glass compositions was determined using the buoyancy method of ASTM C693-93(2013). The linear coefficient of thermal expansion (CTE) over the temperature range 25° C. to 300° C. is expressed in terms of ppm/° C. and was determined using a push-rod dilatometer in accordance with ASTM E228-11. The strain point and anneal point were determined using the beam bending viscosity method of ASTM C598-93(2013). The softening point was determined using the parallel plate viscosity method of ASTM C1351M-96(2012). The Young's modulus, shear modulus, and Poisson's ratio values refer to values as measured by a resonant ultrasonic spectroscopy technique of the general type set forth in ASTM E2001-13, titled “Standard Guide for Resonant Ultrasound Spectroscopy for Defect Detection in Both Metallic and Non-metallic Parts.”

TABLE I

| | A | B | C | D | E | F | G | H | I |
|---|---|---|---|---|---|---|---|---|---|
| SiO₂ | 65.59 | 58.82 | 58.55 | 53.95 | 60.38 | 69.95 | 63.60 | 54.50 | 70.00 |
| Al₂O₃ | 1.92 | 8.56 | 8.53 | 9.00 | 8.09 | 6.63 | 15.70 | 16.20 | 22.50 |
| P₂O₅ | 9.57 | | 1.00 | 3.00 | | | 6.89 | 10.20 | 7.50 |
| B₂O₃ | 22.81 | 25.12 | 25.00 | 28.00 | 23.91 | 17.48 | | 7.02 | |
| MgO | | 0.03 | | | 0.52 | 0.40 | 2.05 | 2.15 | |
| CaO | | 7.44 | 6.89 | | 6.99 | 5.06 | 7.50 | 5.69 | |
| SrO | | | | 6.00 | | 0.34 | 4.03 | 4.15 | |
| BaO | | | | | | 0.02 | | | |
| ZrO₂ | | | | | | | 0.01 | 0.01 | |
| SnO₂ | 0.06 | 0.03 | 0.03 | 0.05 | 0.05 | 0.05 | 0.07 | 0.07 | |
| Density | 2.202 | 2.260 | 2.237 | 2.289 | 2.270 | 2.256 | 2.497 | 2.416 | |
| (g/cc) | | | | | | | | | |
| CTE | 3.82 | 3.52 | 3.52 | 3.91 | 3.44 | 2.95 | 3.44 | 7.74 | |
| (ppm) | | | | | | | | | |
| Strain | 508.2 | 584 | 565.3 | 531.6 | 573.7 | 606.3 | 672.8 | 671.4 | |
| Point | | | | | | | | | |
| ( ° C.) | | | | | | | | | |
| Annealing | 583.9 | 637.2 | 618.2 | 584.6 | 624.7 | 672.0 | 724.5 | 718.6 | |
| Point | | | | | | | | | |
| (° C.) | | | | | | | | | |
| Softening | 996.4 | | 916.2 | 887.8 | | | 1040.0 | | |
| Point (° C.) | | | | | | | | | |
| Young's | 53.57 | 58.12 | 53.81 | 49.86 | 58.40 | 59.85 | 65.73 | 66.05 | |
| modulus | | | | | | | | | |
| (GPa) | | | | | | | | | |
| Shear | 22.04 | 23.37 | 22.00 | 20.04 | 23.79 | 24.41 | 26.69 | 27.15 | |
| modulus | | | | | | | | | |
| (GPa) | | | | | | | | | |
| Poisson's | 0.215 | 0.244 | 0.223 | 0.244 | 0.229 | 0.227 | 0.231 | 0.216 | |
| ratio | | | | | | | | | |

Samples having the compositions shown in Table I were exposed to water vapor containing environments to form glass articles having compressive stress layers. The sample composition and the environment the samples were exposed to, including the temperature, pressure, and exposure time, are shown in Table II below. Each of the treatment environments were saturated with water vapor. The resulting maximum compressive stress and depth of compression as measured by surface stress meter (FSM) is also reported in Table II.

TABLE II

| Glass | | | | | | |
|---|---|---|---|---|---|---|
| Composition | A | | B | | | C |
| Temperature | 200 | 250 | 200 | 400 | 250 | 400 |
| (° C.) | | | | | | |
| Pressure | 0.1 | 0.1 | 0.1 | 0.1 | 0.1 | 0.1 |
| (MPa) | | | | | | |
| Time | 7 | 7 | 7 | 7 | 7 | 7 |
| (days) | | | | | | |
| Compressive | 62 | 22 | 152 | 3 | 140 | 3 |
| Stress | | | | | | |
| (MPa) | | | | | | |
| Depth of | 16 | 28 | 5.1 | 24 | 8 | 36 |
| Compression | | | | | | |
| (um) | | | | | | |
| Glass | | | | | | |
| Composition | D | E | F | G | H | I |
| Temperature | 400 | 400 | 400 | 400 | 400 | 400 |
| (° C.) | | | | | | |
| Pressure | 0.1 | 0.1 | 0.1 | 0.1 | 0.1 | 0.1 |
| (MPa) | | | | | | |
| Time | 7 | 7 | 7 | 7 | 7 | 7 |
| (days) | | | | | | |
| Compressive | 8 | 3 | 13 | 86 | 89 | 110 |
| Stress | | | | | | |
| (MPa) | | | | | | |
| Depth of | 45 | 24.8 | 28 | 16 | 17 | 10 |
| Compression | | | | | | |
| (um) | | | | | | |

A sample of glass composition C was subjected to a multi-step water treatment process. The environments the sample was exposed to in each treatement step, including the temperature, pressure, and exposure time, are shown in Table III below. Each of the treatment environments were saturated with water vapor. The resulting maximum compressive stress and depth of compression as measured by surface stress meter (FSM) is also reported in Table III.

TABLE III

| | Glass Composition | C |
|---|---|---|
| 1st Step | Temperature (° C.) | 400 |
| | Pressure (MPa) | 0.1 |
| | Time (hours) | 168 |
| | Compressive Stress (MPa) | 3 |
| | Depth of Compression (um) | 36 |
| 2nd Step | Temperature (° C.) | 200 |
| | Pressure (MPa) | 1.46 |
| | Time (hours) | 18 |
| | Compressive Stress (MPa) | 128 |
| | Depth of Compression (um) | 18 |

While typical embodiments have been set forth for the purpose of illustration, the foregoing description should not be deemed to be a limitation on the scope of the disclosure or appended claims. Accordingly, various modifications, adaptations, and alternatives may occur to one skilled in the art without departing from the spirit and scope of the present disclosure or appended claims.

What is claimed is:

1. A glass-based article, comprising:
a thickness of less than 2 mm; and
a compressive stress layer extending from a surface of the glass-based article to a depth of compression,
wherein the glass-based article is substantially free of alkali oxides, the compressive stress layer comprises a compressive stress greater than or equal to 10 MPa, and the depth of compression is greater than 5 μm.

2. The glass-based article of claim 1, wherein the compressive stress is greater than or equal to 100 MPa.

3. The glass-based article of claim 1, wherein the depth of compression is greater than or equal to 10 μm.

4. The glass-based article of claim 1, wherein a glass having the same composition as the center of the glass-based article has a coefficient of thermal expansion of less than 10 ppm.

5. The glass-based article of claim 1, wherein the center of the glass-based article comprises greater than or equal to 2 mol % to less than or equal to 10 mol % P₂O₅.

6. The glass-based article of claim 1, wherein the center of the glass-based article comprises greater than or equal to 15 mol % B₂O₃.

7. The glass-based article of claim 6, wherein the center of the glass-based article is substantially free of P₂O₅.

8. A consumer electronic product, comprising:
a housing comprising a front surface, a back surface and side surfaces;
electrical components at least partially within the housing, the electrical components comprising at least a controller, a memory, and a display, the display at or adjacent the front surface of the housing; and
a cover substrate disposed over the display,
wherein at least a portion of at least one of the housing or the cover substrate comprises the glass-based article of claim 1.

9. A glass-based article, comprising:
a compressive stress layer extending from a surface of the glass-based article to a depth of compression,
wherein the glass-based article is substantially free of alkali oxides, the compressive stress layer comprises a compressive stress greater than or equal to 10 MPa, the depth of compression is greater than 5 μm, and a glass having the same composition as the center of the glass-based article has a coefficient of thermal expansion of less than 10 ppm.

10. The glass-based article of claim 9, wherein the compressive stress is greater than or equal to 100 MPa.

11. The glass-based article of claim 9, wherein the depth of compression is greater than or equal to 10 μm.

12. The glass-based article of claim 9, wherein the center of the glass-based article comprises greater than or equal to 2 mol % to less than or equal to 10 mol % P₂O₅.

13. The glass-based article of claim 9, wherein the center of the glass-based article comprises greater than or equal to 15 mol % B₂O₃.

14. The glass-based article of claim 13, wherein the center of the glass-based article is substantially free of P₂O₅.

15. A consumer electronic product, comprising:
a housing comprising a front surface, a back surface and side surfaces;
electrical components at least partially within the housing, the electrical components comprising at least a controller, a memory, and a display, the display at or adjacent the front surface of the housing; and
a cover substrate disposed over the display,
wherein at least a portion of at least one of the housing or the cover substrate comprises the glass-based article of claim 9.

16. A method, comprising:
exposing a glass-based substrate to an environment with a relative humidity of greater than or equal to 75% to form a glass-based article with a compressive stress layer extending from a surface of the glass-based article to a depth of compression,
wherein:
the glass-based substrate is substantially free of alkali oxides;
the depth of compression is greater than 5 μm, and
the compressive stress layer comprises a compressive stress greater than or equal to 10 MPa.

17. The method of claim 16, wherein the environment has a pressure greater than or equal to 0.1 MPa.

18. The method of claim 16, wherein the glass-based substrate comprises greater than or equal to 2 mol % to less than or equal to 10 mol % P₂O₅.

19. The method of claim 16, wherein the glass-based substrate comprises greater than or equal to 15 mol % B₂O₃.

20. The method of claim 19, wherein the glass-based substrate is substantially free of P₂O₅.
